(19) United States
(12) Patent Application Publication
(10) Pub. No.: US 2016/0284581 A1
(43) Pub. Date: Sep. 29, 2016

(54) Method of Manufacturing Semiconductor Device

(71) Applicant: Hitachi Kokusai Electric Inc., Tokyo (JP)

(72) Inventors: Takeshi YASUI, Toyama (JP); Naoya MATSUURA, Toyama (JP); Mitsuru FUKUDA, Toyama (JP); Hiroyuki OGAWA, Toyama (JP)

(21) Appl. No.: 15/181,710

(22) Filed: Jun. 14, 2016

Related U.S. Application Data
(63) Continuation of application No. 13/804,833, filed on Mar. 14, 2013.

(30) Foreign Application Priority Data
Mar. 19, 2012 (JP) 2012-061471

(51) Int. Cl. H01L 21/677; H01L 21/67; H01L 21/687

(52) U.S. Cl. CPC H01L 21/67718; H01L 21/68785; H01L 21/67098

(57) ABSTRACT

Provided are a substrate processing apparatus, a method of processing a substrate, a method of manufacturing a semiconductor device, and a non-transitory computer readable recording medium storing a program for performing the method of manufacturing the semiconductor device, that are capable of improving manufacturing throughput of the apparatus. The substrate processing apparatus includes a substrate to be processed, a transfer chamber under a vacuum atmosphere, a substrate transfer unit installed at the transfer chamber and configured to transfer the substrate, at least two process chambers installed near the transfer chamber and configured to process the substrate, at least two gate valves installed between the transfer chamber and the at least two process chambers, and a control unit configured to control the substrate transfer unit and the at least two gate valves, wherein the control unit opens and closes the at least two gate valves while the substrate transfer unit transfers the substrate.

### CROSS REFERENCE TO RELATED APPLICATIONS

This application is a continuation of U.S. patent application Ser. No. 13/804,833 filed Mar. 14, 2013, and claims priority under 35 U.S.C. §119 to Application No. JP 2012-061471 filed on Mar. 19, 2012, the entire contents of which are hereby incorporated by reference.

### FIELD OF THE INVENTION

The present invention relates to a substrate processing apparatus, a method of processing a substrate, a method of manufacturing a semiconductor device and a non-transitory computer readable recording medium on which a program for performing a method of manufacturing a semiconductor device is recorded, that are capable of efficiently transferring a plurality of substrates when the substrates are continuously processed.

### BACKGROUND

For example, a substrate processing apparatus such as a semiconductor manufacturing apparatus configured to perform predetermined processing on a wafer, which is a semiconductor substrate (a substrate), includes a plurality of process chambers, and film-forming processing or annealing is performed on the wafer in each of the process chambers. In addition, the wafer is transferred between the process chambers by a transfer robot under a vacuum pressure, i.e., a negative pressure.

In addition, a substrate processing apparatus including a plurality of processing furnaces configured to process the wafer, preliminary chambers and configured to temporarily accommodate the wafer, a first transfer apparatus configured to transfer the wafer via a gate valve between the processing furnaces and the preliminary chambers, and a second transfer apparatus configured to transfer the wafer via the gate valve with respect to the preliminary chambers, and a method of manufacturing a semiconductor device are provided. In addition, in order to transfer a wafer to a process chamber, a configuration in which a gate valve of the process chamber becomes OPEN, and then it is determined whether the gate valve is opened by ON or OFF of an opening/closing sensor configured to detect opening/closing of the gate valve is disclosed. Further, a configuration is disclosed in which gate valves are opened, a wafer is transferred to the process chamber from a cassette chamber via a transfer chamber, the valves are closed, and the wafer is processed in a reaction chamber.

### SUMMARY

However, in a manufacturing process of a semiconductor device performed in the substrate processing apparatus, a stoppage time of the transfer robot, which is a substrate transfer unit, by the opening/closing of the gate valve is increased and causes a decrease in throughput.

It is an aspect of the present invention to provide a substrate processing apparatus, a method of processing a substrate, a method of manufacturing a semiconductor device and a non-transitory computer readable recording medium on which a program for performing a method of manufacturing a semiconductor device is recorded, that are capable of improving manufacturing throughput of the apparatus.

According to an aspect of the present invention, there is provided a substrate processing apparatus including: a transfer chamber under an inert atmosphere; a substrate transfer unit installed at the transfer chamber and configured to transfer a substrate; at least two process chambers installed near the transfer chamber and configured to process the substrate; at least two gate valves installed between the transfer chamber and the at least two process chambers; and a control unit configured to control the substrate transfer unit and the at least two gate valves, wherein the control unit opens and closes the at least two gate valves while the substrate transfer unit transfers the substrate.

According to another aspect of the present invention, there is provided a method of processing a substrate including: (a) pivoting a substrate transfer unit in a transfer chamber with a substrate thereon; (b) processing the substrate in at least two process chambers installed near the transfer chamber; and (c) opening and closing at least two gate valves installed between the transfer chamber and the at least two process chambers while the substrate transfer unit pivots with the substrate thereon.

According to another aspect of the present invention, there is provided a method of manufacturing a semiconductor device including: (a) pivoting a substrate transfer unit in a transfer chamber with a substrate thereon; (b) processing the substrate in at least two process chambers installed near the transfer chamber; and (c) opening and closing at least two gate valves installed between the transfer chamber and the at least two process chambers while the substrate transfer unit pivots with the substrate thereon.

In addition, according to another aspect of the present invention, there is provided a non-transitory computer readable recording medium storing a program that causes a computer to perform a method of manufacturing a semiconductor device including: (a) pivoting a substrate transfer unit in a transfer chamber with a substrate thereon; (b) processing the substrate in at least two process chambers installed near the transfer chamber; and (c) opening and closing at least two gate valves installed between the transfer chamber and the at least two process chambers while the substrate transfer unit pivots with the substrate thereon.

### Effects of the Invention

According to the substrate processing apparatus, the method of processing a substrate, the method of manufacturing a semiconductor device and the non-transitory computer readable recording medium on which the program for performing the method of manufacturing the semiconductor device is recorded according to the present invention, manufacturing throughput of the apparatus can be improved.

### BRIEF DESCRIPTION OF THE DRAWINGS

FIG. 1 is a horizontal cross-sectional view showing a configuration example of a substrate processing apparatus according to an embodiment of the present invention;

FIG. 2 is a vertical cross-sectional view showing the configuration example of the substrate processing apparatus according to the embodiment of the present invention;

FIG. 3 is a block diagram showing a configuration example of a control unit according to the embodiment of the present invention;

FIG. 4 is a view showing a configuration example of a process chamber and its periphery according to the embodiment of the present invention;

FIG. 5 is a view showing a gate valve opening/closing sequence according to the embodiment of the present invention;

FIG. 6 is a view showing a gate valve opening/closing sequence according to another embodiment of the present invention; and

FIG. 7 is a view showing a gate valve opening/closing sequence according to a comparative example.

### DETAILED DESCRIPTION

### (1) Configuration of Substrate Processing Apparatus

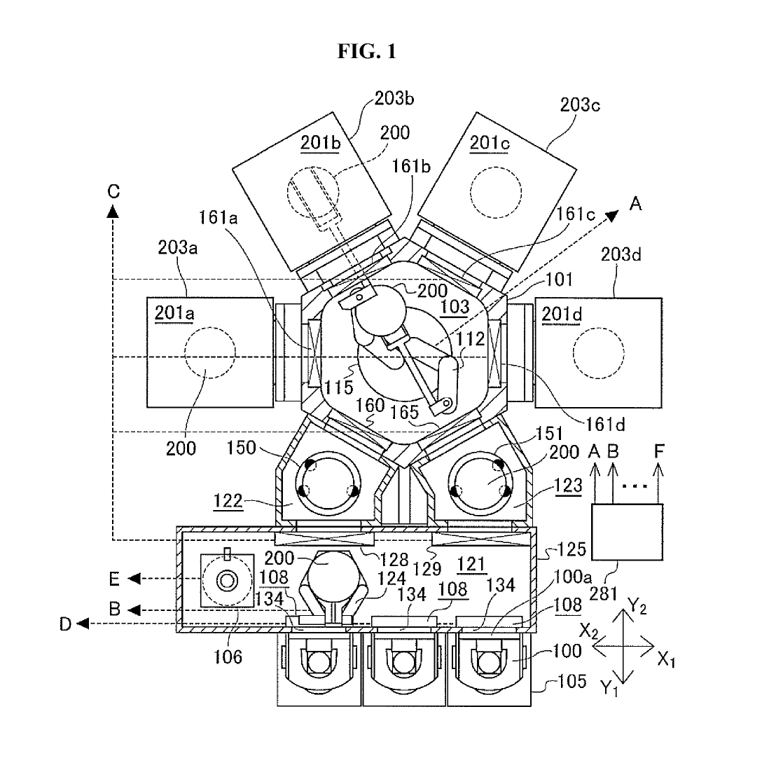

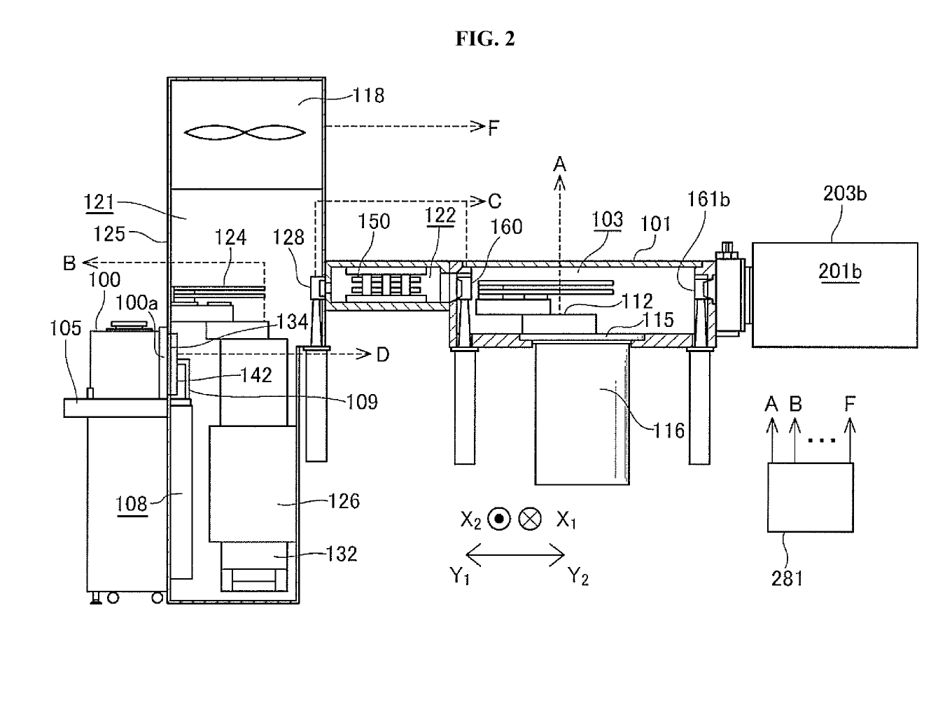

A schematic configuration of a substrate processing apparatus according to an embodiment of the present invention will be described with reference to FIGS. 1 and 2. FIG. 1 is a horizontal cross-sectional view showing a configuration example of a substrate processing apparatus according to an embodiment of the present invention, and FIG. 2 is a vertical cross-sectional view showing the configuration example of the substrate processing apparatus according to the embodiment of the present invention.

Referring to FIGS. 1 and 2, a pod 100 constituted by a front opening united pod (FOUP) is used as a carrier configured to transfer a wafer 200 such as a silicon (Si) substrate within the substrate processing apparatus to which the present invention is applied. The inside of the pod 100 is configured such that the plurality of non-processed wafers 200 or the plurality of processed wafers 200 are housed in a horizontal posture. In addition, in the following description, an X1 direction is referred to as a rightward direction, an X2 direction is referred to as a leftward direction, a Y1 direction is referred to as a forward direction, and a Y2 direction is referred to as a rearward direction.

### (Vacuum Transfer Chamber)

Referring to FIGS. 1 and 2, the substrate processing apparatus includes a vacuum transfer chamber 103 (a transfer module) serving as a transfer chamber, which becomes a transfer space into which the wafer 200 is transferred under a negative pressure. A housing 101 constituting the vacuum transfer chamber 103 has a hexagonal shape when seen in a plan view, and preliminary chambers 122 and 123 and process chambers 201a to 201d, which are described below, are connected to sides of the hexagonal shape via gate valves 160, 165, and 161a to 161d, respectively. A vacuum transfer robot 112 serving as a transfer robot configured to transfer the wafer 200 under the negative pressure is installed at a substantially central portion of the vacuum transfer chamber 103 on a flange 115, which is a base section.

As shown in FIG. 2, the vacuum transfer robot 112 installed in the vacuum transfer chamber 103 is configured to be raised and lowered while maintaining air tightness of the vacuum transfer chamber 103 by an elevator 116 and the flange 115.

### (Preliminary Chamber)

A preliminary chamber 122 (a load lock module) for loading and a preliminary chamber 123 (load lock module) for unloading are connected to two sidewalls disposed at front sides, among six sidewalls of the housing 101, via the gate valves 160 and 165 to constitute structures that can endure the negative pressure.

In addition, a substrate seating frame 150 for a loading chamber is installed in the preliminary chamber 122, and a substrate seating frame 151 for an unloading chamber is installed in the preliminary chamber 123.

### (Atmosphere Transfer Chamber/IO Stage)

An atmosphere transfer chamber 121 (a front end module) is connected to front sides of the preliminary chamber 122 and the preliminary chamber 123 via gate valves 128 and 129. The atmosphere transfer chamber 121 is used under a substantially atmospheric pressure.

An atmosphere transfer robot 124 configured to transfer the wafer 200 is installed in the atmosphere transfer chamber 121. Referring to FIG. 2, the atmosphere transfer robot 124 is configured to be raised and lowered by an elevator 126 installed at the atmosphere transfer chamber 121, and configured to be reciprocally moved in a leftward/rightward direction by a linear actuator 132.

Referring to FIG. 2, a clean unit 118 configured to supply clean air is installed at an upper portion of the atmosphere transfer chamber 121. In addition, referring to FIG. 1, an apparatus 106 (hereinafter referred to as a pre-aligner) to align a notch or an orientation flat formed on the wafer 200 is installed at a left side of the atmosphere transfer chamber 121.

Referring to FIGS. 1 and 2, a substrate loading/unloading port 134 configured to load and unload the wafer 200 into/from the atmosphere transfer chamber 121 and a pod opener 108 are formed at a front of a housing 125 of the atmosphere transfer chamber 121. An 10 stage 105 (a load port) is installed at an opposite side of the pod opener 108, i.e., the outside of the housing 125, via the substrate loading/unloading port 134.

The pod opener 108 includes a closer 142 configured to open and close a cap 100a of the pod 100 and seal the substrate loading/unloading port 134, and a drive mechanism 109 configured to drive the closer 142. The pod opener 108 is configured to open and close the cap 100a of the pod 100 placed on the 10 stage 105 to open and close a substrate entrance so that the wafer 200 enters and exits the pod 100. The pod 100 is supplied into and discharged from the 10 stage 105 by a transfer apparatus in process (RGV) (not shown).

### (Process Chamber)

Referring to FIG. 1, the second process chamber 201b (the process module) and the third process chamber 201c (the process module) configured to perform desired processing on the wafer 200 are closely connected to two sidewalls disposed at rear sides (rear surface sides), among the six sidewalls of the housing 101, via the gate valves 161b and 161c, respectively. Both of the second process chamber 201b and the third process chamber 201c are constituted by cold-wall type processing vessels 203b and 203c.

The first process chamber 201a (the process module) and the fourth process chamber 201d (the process module) are connected to the other two sidewalls opposite to each other, among the six sidewalls of the housing 101, via the gate valves 161a and 161d, respectively. Both of the first process chamber 201a and the fourth process chamber 201d are also constituted by cold-wall type processing vessels 203a and 203d. In each of the process chambers, oxidation processing, nitration processing, etching processing, or the like, which are manufacturing processes of a semiconductor or a semiconductor device, is performed. A specific configuration of each of the process chambers 201a to 201 will be described below.

### (Control Unit)

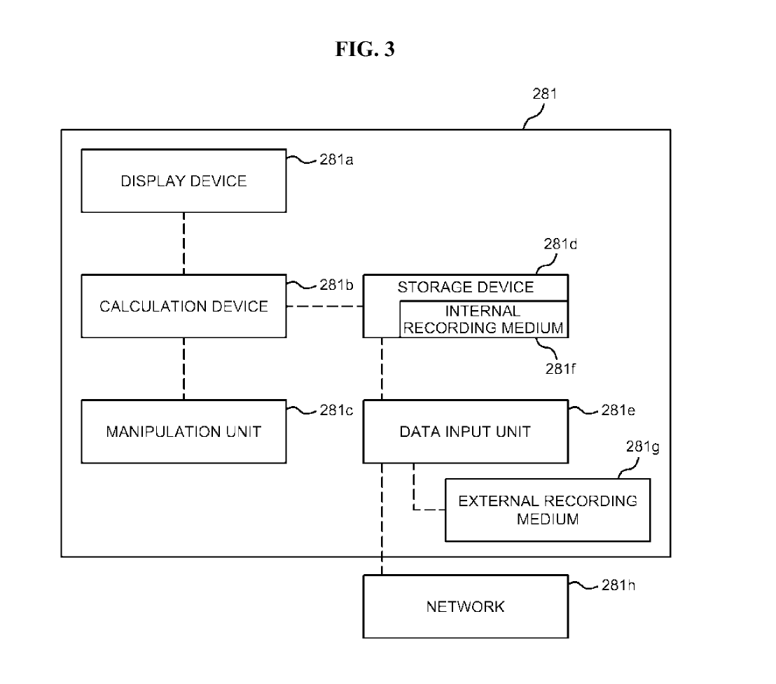

As shown in FIGS. 1 and 2, for example, a controller 281 serving as a control unit is electrically connected to the vacuum transfer robot 112 via a signal line A, the atmosphere transfer robot 124 via a signal line B, the gate valves 160, 161a, 161b, 161c, 161d, 165, 128 and 129 via a signal line C, the pod opener 108 via a signal line D, the pre-aligner 106 via a signal line E, and the clean unit 118 via a signal line F, and also controls operations of the respective units constituting the substrate processing apparatus. As shown in FIG. 3, the controller 281 is connected to a display device 281a, a calculation device 281b, a manipulation unit 281c, a storage device 281d and a data input unit 281e. In addition, the controller 281 is connected to a network 281h via the data input unit 281e. Further, the storage device 281d includes an internal recording medium 281f. That is, the controller 281 includes components serving as a computer, and controls the manipulation unit 281c, the display device 281a, or the like, as the calculation device 281b performs a program stored in the internal recording medium 281f of the storage device 281d. In addition, an external recording medium 281g may be installed to be connected to the data input unit 281e instead of the internal recording medium 281f, or both of the internal recording medium 281f and the external recording medium 281g may be used. Further, the program may be recorded on the internal recording medium 281f installed in the storage device 281d from the beginning, and then the program recorded on the external recording medium 281g connected to the data input unit 281e may be moved to the internal recording medium 281f to be written over the program of the internal recording medium 281f. Here, for example, a hard disk, a CD-ROM, a flash memory, or the like, may be used as the internal recording medium 281f. In addition, for example, a Floppy (registered trademark) disk, a CD-ROM, an MO, a flash memory, or downloading from a network in a semiconductor device manufacturing factory or the Internet, or the like, may be used as the external recording medium 281g.

### (2) Configuration of Process Chamber

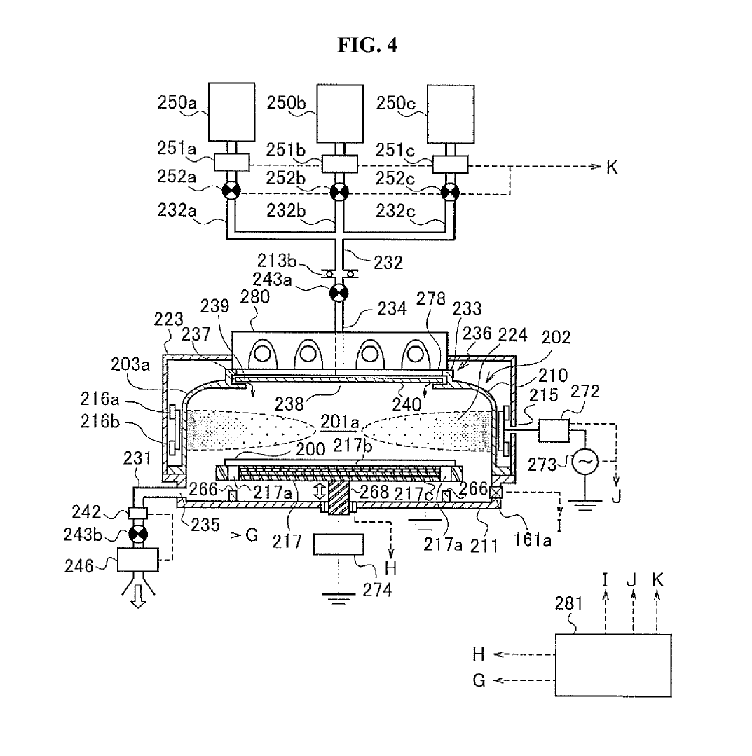

Hereinafter, a configuration and an operation of the process chamber 201a according to the embodiment of the present invention will be described with reference to FIG. 4.

FIG. 4 is a cross-sectional configuration view of an MMT apparatus including the first process chamber 201a among the process chambers 201a to 201d, each of which has the same configuration. The MMT apparatus is an apparatus for processing the wafer 200 such as a silicon substrate or the like using a modified magnetron type plasma source configured to generate high density plasma by an electric field and a magnetic field. Hereinafter, while a configuration example of the first process chamber 201a and its periphery will be described, the same configuration example may be provided to the other process chambers 201b to 201d.

The MMT apparatus includes a processing furnace 202 configured to perform plasma processing on the wafer 200. In addition, the processing furnace 202 includes the processing vessel 203a constituting the first process chamber 201a, a susceptor 217, the gate valve 161a, a shower head 236, a gas exhaust port 235, a first electrode 215, which is a tubular electrode, an upper magnet 216a, a lower magnet 216b, and the controller 281.

### (Process Chamber)

The processing vessel 203a constituting the first process chamber 201a includes a dome type upper vessel 210, which is a first vessel, and a bowl type lower vessel 211, which is a second vessel. In addition, the upper vessel 210 is coated on the lower vessel 211 to form the first process chamber 201a. The upper vessel 210 is formed of a non-metal material such as aluminum oxide (Al₂O₃), quartz (SiO₂), or the like, and the lower vessel 211 is formed of, for example, aluminum (Al).

The gate valve 161a serving as a gate valve is installed at the sidewall of the lower vessel 211. When the gate valve 161a is open, the wafer 200 is loaded into the first process chamber 201a using the above-mentioned vacuum transfer robot 112, or the wafer 200 is unloaded to the outside of the first process chamber 201a. As the gate valve 161a is closed, the inside of the first process chamber 201a is hermetically sealed.

### (Substrate Support Unit)

The susceptor 217 serving as a substrate seating frame configured to support the wafer 200 is disposed at a center of a bottom side in the first process chamber 201a. The susceptor 217 is formed of a non-metal material such as aluminum nitride (AlN), ceramics, quartz, or the like, to reduce metal contamination to a film or the like formed on the wafer 200.

A resistance heating heater 217b serving as a heating mechanism is integrally buried in the susceptor 217 to heat the wafer 200. When power is supplied to the resistance heating heater 217b, a surface of the wafer 200 is heated to, for example, room temperature or more, preferably, 200° C. to 700° C., or about 750° C.

The susceptor 217 is electrically insulated from the lower vessel 211. A second electrode 217c serving as an electrode configured to vary impedance is installed in the susceptor 217. The second electrode 217c is grounded via an impedance variable mechanism 274. The impedance variable mechanism 274 includes a coil or a variable condenser, and is configured to control potential of the wafer 200 via the second electrode 217c and the susceptor 217 by controlling the number of patterns of the coil and a capacity value of the variable condenser.

A susceptor elevation mechanism 268 configured to raise and lower the susceptor 217 is installed at the susceptor 217. A through-hole 217a is formed in the susceptor 217. At least three substrate lift pins 266 configured to push up the wafer 200 are installed at a bottom surface of the above-mentioned lower vessel 211. In addition, the through-hole 217a and the substrate lift pin 266 are disposed such that the substrate lift pin 266 passes through the through-hole 217a with no contact with the susceptor 217 when the susceptor 217 is lowered by the susceptor elevation mechanism 268.

The substrate support unit according to the embodiment is mainly constituted by the susceptor 217 and the resistance heating heater 217b.

### (Lamp Heating Apparatus)

A light transmission window 278 is disposed on an upper surface of the processing vessel 203a. A lamp heating apparatus 280 (a lamp heater) serving as a substrate heating body, which is a light source configured to emit, for example, infrared light, is installed at the outside of the processing vessel 203a corresponding to the light transmission window 278. The lamp heating apparatus 280 is configured to heat the wafer 200 to exceed a temperature of 700° C. The lamp heating apparatus 280 is used as an auxiliary heater when heating processing of more than 700° C. is performed with respect to the wafer 200, in the above-mentioned resistance heating heater 217b having an upper limit temperature of, for example, about 700° C.

### (Gas Supply Unit)

The shower head 236 configured to supply a processing gas such as a reaction gas or the like into the first process chamber 201a is installed at an upper portion of the first process chamber 201a. The shower head 236 includes a cover 233 having a cap shape, a gas introduction port 234, a buffer chamber 237, an opening 238, a shielding plate 240 (a shower plate), and a gas outlet port 239.

A downstream end of a gas supply pipe 232 configured to supply the processing gas into the buffer chamber 237 is connected to the gas introduction port 234 via an O-ring 213b serving as a sealing member and a valve 243a serving as an opening/closing valve. The buffer chamber 237 functions as a dispersion space configured to disperse a gas introduced from the gas introduction port 234.

A downstream end of a nitrogen gas supply pipe 232a configured to supply nitrogen (N₂) gas, which is a nitrogen atom-containing gas, a downstream end of a hydrogen gas supply pipe 232b configured to supply hydrogen (H₂) gas, which is a hydrogen atom-containing gas, and a downstream end of a rare gas supply pipe 232c configured to supply a rare gas, which is a dilution gas such as helium (He) gas, argon (Ar) gas, or the like, are connected to and joined with an upstream side of the gas supply pipe 232.

A nitrogen gas cylinder 250a, a mass flow controller 251a serving as a flow rate control device, and a valve 252a serving as an opening/closing valve, are connected to the nitrogen gas supply pipe 232a in a sequence from the upstream side. A hydrogen gas cylinder 250b, a mass flow controller 251b serving as a flow rate control device, and a valve 252b serving as an opening/closing valve, are connected to the hydrogen gas supply pipe 232b in sequence from the upstream side. A rare gas cylinder 250c, a mass flow controller 251c serving as a flow rate control device, and a valve 252c serving as an opening/closing valve, are connected to the rare gas supply pipe 232c in sequence from the upstream side.

The gas supply pipe 232, the nitrogen gas supply pipe 232a, the hydrogen gas supply pipe 232b, and the rare gas supply pipe 232c are formed of a non-metal material such as quartz, aluminum oxide, or the like, and a metal material such as stainless use steel (SUS), or the like. As the valves 252a to 252c installed at the pipes are opened and closed, N₂ gas, H₂ gas, and a rare gas can be freely supplied into the first process chamber 201a via the buffer chamber 237 while controlling a flow rate thereof by the mass flow controller 251a to 251c.

A gas supply unit according to the embodiment is mainly constituted by the gas supply pipe 232, the nitrogen gas supply pipe 232a, the hydrogen gas supply pipe 232b, the rare gas supply pipe 232c, the nitrogen gas cylinder 250a, the hydrogen gas cylinder 250b, the rare gas cylinder 250c, the mass flow controllers 251a to 251c and the valves 252a to 252c.

In addition, while the case in which the gas cylinders for N2 gas, H2 gas, a rare gas, and so on, are installed has been described, the present invention is not limited thereto but an oxygen (O₂) gas cylinder may be installed instead of the nitrogen gas cylinder 250a or the hydrogen gas cylinder 250b. Further, when a ratio of nitrogen in the reaction gas supplied into the first process chamber 201a is increased, an ammonia (NH₃) gas cylinder may be further installed so that NH₃ gas is added to N₂ gas.

### (Gas Exhaust Unit)

The gas exhaust port 235 configured to exhaust a reaction gas or the like from the inside of the first process chamber 201a is installed under the sidewall of the lower vessel 211. An upstream end of a gas exhaust pipe 231 configured to exhaust a gas is connected to the gas exhaust port 235. An APC 242 serving as a pressure controller, a valve 243b serving as an opening/closing valve, and a vacuum pump 246 serving as an exhaust apparatus are installed at the gas exhaust pipe 231 in sequence from the upstream side. As the vacuum pump 246 is operated to open the valve 243b, the inside of the first process chamber 201a can be exhausted. In addition, as an opening angle of the APC 242 is adjusted, a pressure value in the first process chamber 201a can be adjusted.

A gas exhaust unit according to the embodiment is mainly constituted by the gas exhaust port 235, the gas exhaust pipe 231, the APC 242, the valve 243b, and the vacuum pump 246.

### (Plasma Generating Unit)

The first electrode 215 is installed at an outer circumference of the processing vessel 203a [the upper vessel 210] to surround a plasma generating region 224 in the first process chamber 201a. The first electrode 215 has a tubular shape, for example, a cylindrical shape. The first electrode 215 is connected to a radio frequency power source 273 configured to generate radio frequency power via a matching device 272 configured to perform matching of the impedance. The first electrode 215 functions as a discharge mechanism configured to excite the gas supplied into the first process chamber 201a to generate plasma.

The upper magnet 216a and the lower magnet 216b are installed at an upper end and a lower end of an outer surface of the first electrode 215, respectively. The upper magnet 216a and the lower magnet 216b are constituted by a permanent magnet having a tubular shape, for example, a ring shape.

The upper magnet 216a and the lower magnet 216b have magnetic poles formed at both ends (i.e., an inner circumferential end and an outer circumferential end of each magnet) in a radial direction of the first process chamber 201a. The magnetic poles of the upper magnet 216a and the lower magnet 216b are disposed in opposite directions. That is, the magnetic poles of the inner circumferential portions of the upper magnet 216a and the lower magnet 216b have different polarities. Accordingly, a line of magnetic force in a cylindrical axial direction is formed along an inner surface of the first electrode 215.

Magnetron discharge plasma is generated in the first process chamber 201a by forming a magnetic field using the upper magnet 216a and the lower magnet 216b, introducing a mixed gas of, for example, N₂ gas and H₂ gas into the first process chamber 201a, and then supplying radio frequency power to the first electrode 215 to form an electric field. As the emitted electrons are circumferentially moved by the above-mentioned electromagnetic field, an electrolytic dissociation generating rate of the plasma can be increased to generate high density plasma having a long lifespan.

A plasma generating unit according to the embodiment is mainly constituted by the first electrode 215, the matching device 272, the radio frequency power source 273, the upper magnet 216a, and the lower magnet 216b.

In addition, a shielding plate 223 formed of a metal and configured to efficiently shield an electromagnetic field is installed around the first electrode 215, the upper magnet 216a and the lower magnet 216b such that an electromagnetic field formed thereby does not exert a bad influence on an apparatus such as an external environment, another processing furnace, or the like.

### (Control Unit)

In addition, the controller 281 serving as a control unit is connected to the APC 242, the valve 243b and the vacuum pump 246 via a signal line G, the susceptor elevation mechanism 268 via a signal line H, the gate valve 161a via a signal line I, the matching device 272 and the radio frequency power source 273 via a signal line J, the mass flow controllers 251a to 251c and the valves 252a to 252c via a signal line K, and the resistance heating heater 217b, the impedance variable mechanism 274, or the like, buried in the susceptor 217 via a signal line (not shown), to control them.

### (3) Substrate Processing Process

Hereinafter, a processing process of processing the wafer 200, specifically, a heating processing process using plasma, which is one process of a manufacturing process of a semiconductor device using the substrate processing apparatus having the above-mentioned configuration, will be described with reference to FIGS. 1 to 4. In addition, in the following description, operations of the respective units constituting the substrate processing apparatus are controlled by the controller 281.

(Transfer Process from Atmosphere Transfer Chamber Side)

For example, in a state in which 25 non-processed wafers 200 are accommodated in the pod 100, the pod 100 is transferred into the substrate processing apparatus configured to perform a heating processing process by a transfer apparatus in process. Referring to FIGS. 1 and 2, the transferred pod 100 is delivered from the transfer apparatus in process and placed on the 10 stage 105. The cap 100a of the pod 100 is removed by the pod opener 108 to open a substrate entrance of the pod 100.

When the pod 100 is opened by the pod opener 108, the atmosphere transfer robot 124 installed at the atmosphere transfer chamber 121 picks up the wafer 200 from the pod 100 to load the wafer 200 into the preliminary chamber 122, and transfers the wafer 200 to the substrate seating frame 150. During the transfer operation, the gate valve 160 of the vacuum transfer chamber 103 side of the preliminary chamber 122 is closed, and a negative pressure in the vacuum transfer chamber 103 is maintained.

When transfer of a plurality of, for example, 25 wafers 200 accommodated in the pod 100 into the substrate seating frame 150 is completed, the gate valve 128 is closed and the inside of the preliminary chamber 122 is exhausted by an exhaust apparatus (not shown) under a negative pressure.

When the inside of the preliminary chamber 122 reaches a predetermined pressure value, the gate valve 160 is opened and the preliminary chamber 122 comes in communication with the vacuum transfer chamber 103.

Next, the vacuum transfer robot 112 loads the wafer 200 from the inside of the preliminary chamber 122 to the inside of the vacuum transfer chamber 103. Simultaneously or consecutively (sequentially), the wafer 200 is loaded into the vacuum transfer chamber 103 and the gate valve 160 is closed, for example, the gate valve 161a is opened and the vacuum transfer chamber 103 comes in communication with the first process chamber 201a.

Here, the respective operations of the loading of the wafer 200 into the first process chamber 201a, substrate processing which involves the heating processing, and the unloading of the wafer 200 into the first process chamber 201a will be described using FIG. 4 including the process chamber 201a.

### (Loading Process)

First, the vacuum transfer robot 112 loads the wafer 200 from the inside of the vacuum transfer chamber 103 to the inside of the first process chamber 201a to transfer the wafer 200 onto the susceptor 217 in the first process chamber 201a. Specifically, first, the susceptor 217 is lowered, and a tip of the substrate lift pin 266 protrudes a predetermined height from a surface of the susceptor 217 through the through-hole 217a of the susceptor 217. In this state, as described above, the gate valve 161a installed at the lower vessel 211 is opened. Next, the wafer 200 supported by the vacuum transfer robot 112 is placed on the tip of the substrate lift pin 266. Next, the vacuum transfer robot 112 is retracted to the outside of the process chamber 201a. Next, the gate valve 161a is closed, and the susceptor 217 is raised by the susceptor elevation mechanism 268. As a result, the wafer 200 is placed on a surface of the susceptor 217. The wafer 200 placed on the susceptor 217 is further raised to a position at which the wafer 200 is processed.

As described above, after the gate valve 161a is closed, the substrate processing that involves the desired heating processing is performed in the first process chamber 201a according to the following sequence.

### (Temperature Increasing/Pressure Regulating Process)

The resistance heating heater 217b buried in the susceptor 217 is previously heated. The wafer 200 is heated to a substrate processing temperature within a range, for example, from room temperature to 700° C. by the resistance heating heater 217b. The pressure in the process chamber 201a is maintained within a range of, for example, 0.1 Pa to 300 Pa using the vacuum pump 246 and an APC valve 242

In addition, in the processing furnace 202 having the above-mentioned configuration, a temperature of the wafer 200 that can be heated by the resistance heating heater 217b buried in the susceptor 217 is up to about 700° C. For this reason, the substrate processing requiring the processing temperature of higher than 700° C. cannot be easily performed by the resistance heating heater 217b alone.

For this reason, in order to enable the substrate processing requiring the processing temperature of higher than 700° C., as described above, in addition to the resistance heating heater 217b, the lamp heating apparatus 280 (the lamp heater) serving as the substrate heating body, which is a light source configured to emit infrared light, is further added to the processing furnace 202. In the temperature increasing/pressure regulating process, according to the necessity, the lamp heating apparatus 280 is used subsidiarily to heat the wafer 200 to the substrate processing temperature of higher than 700° C.

### (Heating Processing Process)

After the wafer 200 is heated to the substrate processing temperature, the following substrate processing which involves the heating processing is performed while maintaining the wafer 200 at a predetermined temperature. That is, a processing gas according to the desired processing such as oxidation, nitration, film-forming, etching, or the like, is supplied from the gas introduction port 234 toward a surface (a processing surface) of the wafer 200 disposed in the process chamber 201a in the form of a shower via the opening 238 of a shower plate 240. Simultaneously, radio frequency power is supplied to the first electrode 215 from the radio frequency power source 273 via the matching device 272. The supplied power is within a range of, for example, 100 W to 1,000 W, preferably, 800 W. In addition, the impedance variable mechanism 274 is previously set to a desired impedance value.

A magnetron is discharged by a magnetic field of the upper and lower magnets 216a and 216b having a tubular shape to trap a charge in an upper space of the wafer 200, generating high density plasma in the plasma generating region 224. The plasma processing such as formation of an oxide layer or a nitride layer, formation of a thin film, etching, or the like, is performed on the surface of the wafer 200 on the susceptor 217 by the high density plasma.

In addition, the controller 281 controls power ON/OFF of the radio frequency power source 273, adjustment of the matching device 272, opening/closing of the valves 252a to 252c and 243a, flow rates of the mass flow controllers 251a to 251c, a valve opening angle of the APC valve 242, opening/closing of the valve 243b, operation/stoppage of the vacuum pump 246, a raising and lowering operation of the susceptor elevation mechanism 268, opening/closing of the gate valve 161a, and ON/OFF of a radio frequency power source configured to supply power such as radio frequency or the like to the resistance heating heater 217b buried in the susceptor 217.

### (Unloading Process)

The wafer 200 processed in the first process chamber 201a is transferred by a transfer unit to the outside of the first process chamber 201a in a reverse operation of the loading of the wafer 200 before the cooling of the wafer 200 is terminated, i.e., while the wafer 200 is maintained at a temperature relatively near the substrate processing temperature. That is, when the substrate processing with respect to the wafer 200 is completed, the gate valve 161a is opened. In addition, as the susceptor 217 is lowered to a position at which the wafer 200 is transferred and the tip of the substrate lift pin 266 protrudes from the through-hole 217a of the susceptor 217, the wafer 200 can be raised. The processed wafer 200 is unloaded into the vacuum transfer chamber 103 by the vacuum transfer robot 112. After the unloading, the gate valve 161a is closed.

As described above, the loading operation of the wafer 200 into the first process chamber 201a, the substrate processing which involves the heating processing, and the unloading operation of the wafer 200 from the inside of the first process chamber 201a are terminated.

The vacuum transfer robot 112 transfers the processed wafer 200 unloaded from the first process chamber 201a into the preliminary chamber 123. After the wafer 200 is transferred to the substrate seating frame 151 in the preliminary chamber 123, the preliminary chamber 123 is closed by the gate valve 165.

As the above-mentioned operations are repeated, a predetermined number of, for example, 25 wafers 200 loaded in the preliminary chamber 122 are sequentially processed.

### (Transfer Process Toward Atmosphere Transfer Chamber)

When the substrate processing with respect to all of the wafers 200 loaded into the preliminary chamber 122 are terminated, all of the processed wafers 200 are accommodated in the preliminary chamber 123 and the preliminary chamber 123 is closed by the gate valve 165, the inside of the preliminary chamber 123 is returned to about the atmospheric pressure by an inert gas. When the inside of the preliminary chamber 123 is returned to about the atmospheric pressure, the gate valve 129 is opened, and the cap 100a of the empty pod 100 placed on the IO stage 105 is opened by the pod opener 108.

Next, the atmosphere transfer robot 124 of the atmosphere transfer chamber 121 picks the wafer 200 from the substrate seating frame 151 in the preliminary chamber 123 to unload the wafer 200 into the atmosphere transfer chamber 121 and accommodate the wafer 200 in the pod 100 through the substrate loading/unloading port 134 of the atmosphere transfer chamber 121. For example, when the 25 processed wafers 200 are completely accommodated in the pod 100, the cap 100a of the pod 100 is closed by the pod opener 108. The closed pod 100 is transferred to the following process from above the IO stage 105 by the transfer apparatus in process.

While the above-mentioned operation has been exemplarily described with reference to the case in which the first process chamber 201a is used, the same operation is performed when the second process chamber 201b, the third process chamber 201c and the fourth process chamber 201d are used. In addition, while the preliminary chamber 122 is used for loading and the preliminary chamber 123 is used for unloading in the substrate processing apparatus, the preliminary chamber 123 may be used for loading and the preliminary chamber 122 may be used for unloading.

In addition, in the inside of the first process chamber 201a, the inside of the second process chamber 201b, the inside of the third process chamber 201c, and the inside of the fourth process chamber 201d, the same processing may be performed, or different kinds of processing may be performed. When the different kinds of processing are performed in the inside of the first process chamber 201a, the inside of the second process chamber 201b, the inside of the third process chamber 201c, and the inside of the fourth process chamber 201d, for example, the processing may be performed on the wafer 200 in the first process chamber 201a and then other processing may be performed in the second process chamber 201b. In addition, after the processing is performed on the wafer 200 in the first process chamber 201a, other processing may be performed in the second process chamber 201b, and then other processing may be further performed in the third process chamber 201c or the fourth process chamber 201d. Further, when the other processing is performed in the second process chamber 201b after the processing is performed on the wafer 200 in the first process chamber 201a, the wafer 200 may pass through the preliminary chamber 122 or the preliminary chamber 123.

In addition, the number of wafers 200 processed by the apparatus may be one or more. Similarly, the number of wafers stored in the preliminary chamber 122 or the preliminary chamber 123 may be one or more.

Further, while the processed wafer 200 is loaded and cooled in the preliminary chamber 122, the gate valve 160 of the preliminary chamber 122 may be opened and closed, the wafer may be loaded into the process chamber, and the wafer processing may be performed. Similarly, while the processed wafer 200 is loaded and cooled in the preliminary chamber 123, the gate valve of the preliminary chamber 123 may be opened and closed, the wafer may be loaded into the process chamber, and the wafer processing may be performed. Here, when the gate valve of a substantial atmosphere side is opened before a sufficient cooling time has elapsed, the preliminary chamber 122, the preliminary chamber 123, or electric parts connected to the periphery of the preliminary chambers may be damaged due to radiant heat of the wafer 200. For this reason, when a high temperature wafer is cooled, while the processed wafer having a large amount of radiant heat is loaded and cooled in the preliminary chamber 122, the gate valve of the preliminary chamber 123 may be opened and closed, the wafer may be loaded into the process chamber, and the wafer processing may be performed. Similarly, while the processed wafer is loaded and cooled in the preliminary chamber 123, the gate valve of the preliminary chamber 122 may be opened and closed, the wafer is loaded into the process chamber, and the wafer processing may be performed.

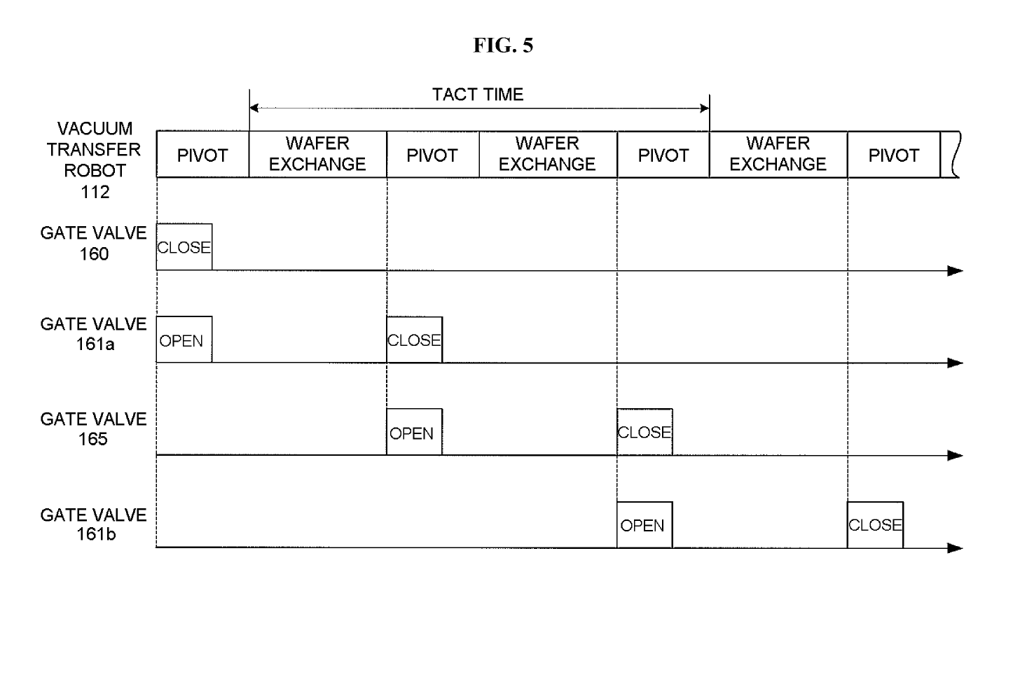

Next, a gate valve opening/closing sequence according to the embodiment of the present invention will be described below. FIG. 5 is a view showing the gate valve opening/closing sequence according to the embodiment of the present invention.

According to the sequence of the present invention, for example, the vacuum transfer robot 112 unloads the non-processed wafer 200 from the preliminary chamber 122. After the unloading, the gate valve 160 of the preliminary chamber 122 which is a transfer origin is closed during pivotal movement of the vacuum transfer robot 112, and simultaneously, the gate valve 161a of the first process chamber 201a which is a transfer destination is opened. Next, the processed wafer 200 is unloaded from the inside of the first process chamber 201a and the non-processed wafer 200 is loaded into the first process chamber 201a so that desired processing is performed in the first process chamber 201a. The gate valve 165 of the preliminary chamber 123 which is a transfer destination is opened at the same time the gate valve 161a of the first process chamber 201a which is a transfer origin is closed during pivotal movement of the vacuum transfer robot 112 with the processed substrate 200 thereon. Here, as shown in FIG. 5, when an opening/closing time of the gate valve of the transfer origin and the gate valve of the transfer destination is smaller than a pivot time of the vacuum transfer robot 112, a stoppage time of the vacuum transfer robot 112 is removed to improve transfer efficiency.

In addition, even when the opening/closing of the gate valve of the transfer origin and the gate valve of the transfer destination is larger than the pivot time of the vacuum transfer robot 112, the stoppage time of the vacuum transfer robot 112 becomes a minimum value.

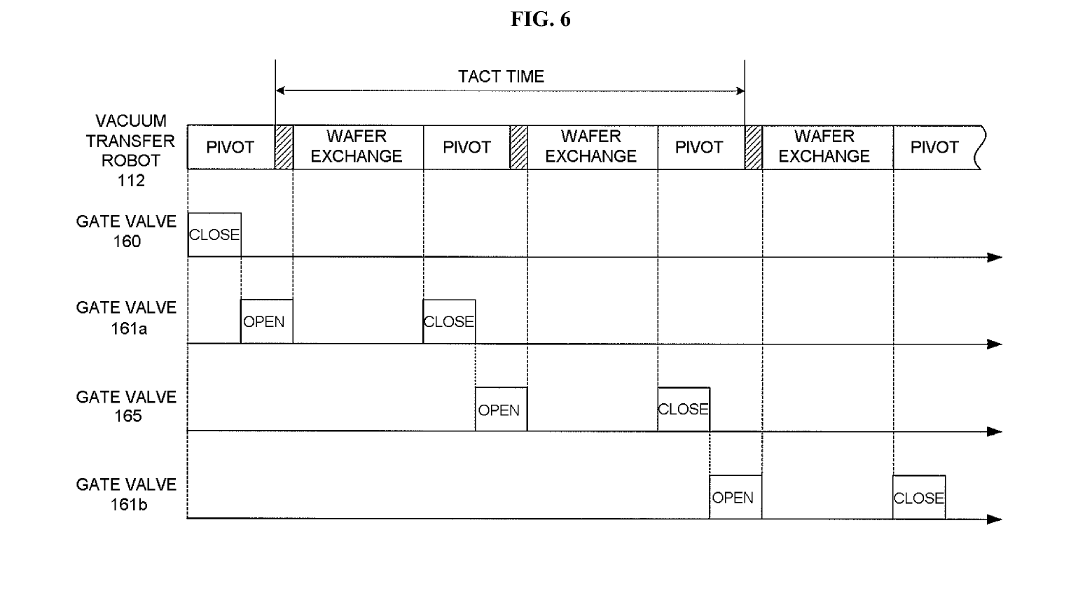

Next, a gate valve opening/closing sequence according to another embodiment will be described. FIG. 6 is a view showing the gate valve opening/closing sequence according to the other embodiment of the present invention.

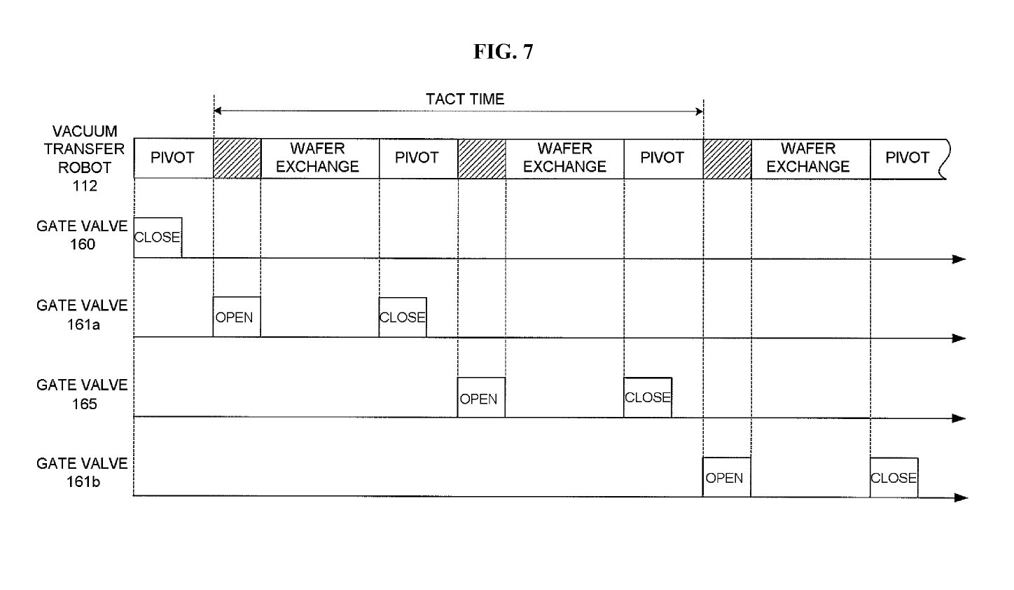

According to the sequence of embodiment, for example, the non-processed wafer 200 is unloaded from the preliminary chamber 122, the gate valve 160 of the preliminary chamber 122 which is a transfer origin is closed during pivotal movement of the vacuum transfer robot 112, and then the gate valve 161a of the first process chamber 201a which is a transfer destination is opened. Then, the processed wafer 200 is unloaded and the non-processed wafer 200 is loaded into the first process chamber 201a so that desired processing is performed in the first process chamber 201a. The processed wafer 200 is unloaded from the first process chamber 201a, the gate valve 161a of the first process chamber 201a which is a transfer origin is closed during pivotal movement of the vacuum transfer robot 112, and sequentially (consecutively), the gate valve 165 of the preliminary chamber 123 which is a transfer destination is opened. Here, as shown in FIG. 6, even when a sum of the opening/closing time of the gate valve of the transfer origin and the gate valve of the transfer destination is larger than the pivot time of the vacuum transfer robot 112, since the stoppage time (oblique lines of FIG. 6) of the vacuum transfer robot 112 is also smaller than a stoppage time (oblique lines of FIG. 7 to be described below) of a gate valve opening/closing sequence according to a comparative example (to be described below), efficiency is good. In addition, generation of particles from the process chamber is suppressed.

Further, when a sum of the opening/closing of the gate valve of the transfer origin and the gate valve of the transfer destination is smaller than the pivot time of the vacuum transfer robot 112, the vacuum transfer robot 112 does not waste time, thus improving transfer efficiency.

Next, a gate valve opening/closing sequence according to a comparative example. FIG. 7 is a view showing the gate valve opening/closing sequence according to the comparative example of the present invention.

In the sequence according to the comparative example, for example, while the vacuum transfer robot 112 is pivoted at the same time the non-processed wafer is unloaded from the preliminary chamber 122 and the gate valve 160 is closed, after pivoting toward the gate valve 161a of the first process chamber 201a which is a transfer destination, it is confirmed that the gate valve 160 of the preliminary chamber 122 which is a transfer origin is closed, and the gate valve 161a of the first process chamber 201a which is the transfer destination is opened. In addition, the processed wafer 200 is unloaded and the non-processed wafer 200 is loaded into the first process chamber 201a so that desired processing is performed in the first process chamber 201a. The processed wafer 200 is unloaded from the first process chamber 201a, the gate valve 161a of the first process chamber 201a which is a transfer origin is closed, the vacuum transfer robot 112 is pivoted toward the gate valve 165 of the unloaded place, and then it is confirmed that the gate valve 161a of the first process chamber 201a which is the transfer origin is closed and the gate valve 165 of the preliminary chamber 123 which is a transfer destination is opened.

In the sequence according to the above-mentioned comparative example, the stoppage time (oblique lines of FIG. 7) of the vacuum transfer robot 112 is increased to decrease throughput.

That is, according to the above-mentioned embodiment, a waiting time of the vacuum transfer robot 112 for the opening/closing of the gate valve can be reduced by simultaneously or consecutively (sequentially) opening/closing the gate valve of the transfer origin and the gate valve of the transfer destination during the transfer operation of the vacuum transfer robot 112 serving as the substrate transfer unit.

In addition, as the gate valve of the transfer origin and the gate valve of the transfer destination are continuously opened and closed, inferiority due to simultaneous opening of the plurality of gate valves [malfunction due to contamination or a difference in pressure] can be prevented and transfer efficiency can be improved.

Further, when a condition of opening the gate valve of the transfer destination is not provided, an opening sequence may be started as if the condition were provided.

Furthermore, simultaneous opening/closing of the gate valve or continuous opening/closing of the gate valve may be selected according to process contents of the process chamber.

In addition, periods of the gate valve of the transfer origin and the gate valve of the transfer destination at fully open state may overlap during the pivotal movement of the vacuum transfer robot 112. Accordingly, a transfer time of the wafer can be reduced.

As described above, according to the embodiment, the number of processed substrates per unit time can be increased without design change of the apparatus, improving manufacturing throughput of the substrate processing apparatus.

In addition, as described in the embodiment, it has been found that heating of the vacuum transfer robot 112 can be reduced by further controlling the opening/closing of the gate valve. For example, the process chamber 201b, the vacuum transfer chamber 103 and the preliminary chamber 123, which are heated by preparing timings at which to open the gate valve 161b of the process chamber and the gate valve 165 of the preliminary chamber when the heated wafer is transferred from the process chamber 201b to the preliminary chamber 123, are connected. An area of absorbing radiant heat from the process chamber 201b or the wafer 200 heated as described above or heat reflected to the vacuum transfer chamber 103 can be increased. Here, the radiant heat absorption area is an area obtained by summing an inner wall area of the vacuum transfer chamber 103 and an inner wall area of the preliminary chamber 123. As the absorption area is increased, heating of the vacuum transfer chamber 103 can be reduced, and a number of continuously transferred heated wafers can be increased.

In addition, while the embodiment of the present invention has been specifically described, the present invention is not limited thereto but may be variously modified without departing from the spirit of the present invention.

### EXEMPLARY MODES OF THE INVENTION

Hereinafter, exemplary modes of the present invention will be supplementarily noted.

### Supplementary Note 1

An aspect of the present invention is a substrate processing apparatus including:

a substrate to be processed;

a transfer chamber under a vacuum atmosphere;

a substrate transfer unit installed at the transfer chamber and configured to transfer the substrate;

at least two process chambers installed near the transfer chamber and configured to process the substrate;

at least two gate valves installed between the transfer chamber and the at least two process chambers; and

a control unit configured to control the substrate transfer unit and the at least two gate valves,

wherein the control unit opens and closes the at least two gate valves while the substrate transfer unit transfers the substrate.

### Supplementary Note 2

Preferably, the control unit sequentially opens and closes the at least two gate valves while the substrate transfer unit pivots with the substrate thereon.

### Supplementary Note 3

In addition, preferably, the control unit controls the at least two gate valves such that periods of the at least two gate valves at fully open state overlap while the substrate transfer unit pivots with the substrate thereon.

### Supplementary Note 4

Another aspect of the present invention is a method of manufacturing a semiconductor device including:

(a) causing a substrate transfer unit installed in a transfer chamber serving as a transfer space of a substrate to pivot the substrate in the transfer chamber;

(b) processing the substrate in at least two process chambers installed near the transfer chamber and serving as a processing space of the substrate; and

(c) causing a control unit to open and close at least two gate valves installed between the transfer chamber and the at least two process chambers while the substrate transfer unit pivots with the substrate thereon.

### Supplementary Note 5

In addition, preferably, in the method of manufacturing the semiconductor device according to supplementary note 4, the step (c) includes sequentially opening/closing the at least two gate valves while the substrate transfer unit pivots with the substrate thereon.

### Supplementary Note 6

Further, preferably, in the method of manufacturing the semiconductor device according to supplementary note 4, the step (c) includes controlling periods of the at least two gate valves at fully open state to overlap while the substrate transfer unit pivots with the substrate thereon.

### Supplementary Note 7

Another aspect of a method of processing a substrate including:

(a) causing a substrate transfer unit installed in a transfer chamber serving as a transfer space of a substrate to pivot the substrate in the transfer chamber;

(b) processing the substrate in at least two process chambers installed near the transfer chamber and serving as a processing space of the substrate; and

(c) causing a control unit to open and close at least two gate valves installed between the transfer chamber and the at least two process chambers while the substrate transfer unit pivots with the substrate thereon.

### Supplementary Note 8

Another aspect of the present invention is a non-transitory computer readable recording medium storing a program that causes a computer to perform the method of manufacturing the semiconductor device according to supplementary note 4 is recorded.

### Supplementary Note 9

Another aspect of the present invention is a non-transitory computer readable recording medium storing a program that causes a computer to perform the method of manufacturing the semiconductor device according to supplementary note 5 is recorded.

### Supplementary Note 10

Another aspect of the present invention is a non-transitory computer readable recording medium storing a program that causes a computer to perform the method of manufacturing the semiconductor device according to supplementary note 6 is recorded.

### Supplementary Note 11

Another aspect of the present invention is a method of manufacturing a semiconductor device using a substrate processing apparatus including: a substrate to be processed; a transfer chamber under a vacuum atmosphere; a substrate transfer unit installed at the transfer chamber and configured to transfer the substrate; at least two process chambers installed near the transfer chamber and configured to process the substrate; at least two gate valves installed between the transfer chamber and the at least two process chambers; and a control unit configured to control the substrate transfer unit and the at least two gate valves, wherein the control unit opens and closes the at least two gate valves while the substrate transfer unit transfers the substrate.

What is claimed is:

1. A method of manufacturing a semiconductor device, comprising:
(a) transferring a substrate from a preliminary chamber into a process chamber via a transfer chamber; and
(b) processing the substrate in the process chamber,
wherein the step (a) comprises:
(a-1) opening a first gate valve disposed between the preliminary chamber and the transfer chamber;
(a-2) transferring the substrate from the preliminary chamber into the transfer chamber by a substrate transfer unit;
(a-3) closing the first gate valve;
(a-4) pivoting the substrate transfer unit in the transfer chamber with the substrate thereon;
(a-5) opening a second gate valve disposed between the transfer chamber and the process chamber;
(a-6) transferring the substrate from the transfer chamber into the process chamber; and
(a-7) closing the second gate valve, and
wherein the steps (a-3) and (a-5) are performed while performing the step (a-4).

2. The method according to claim 1, wherein the steps (a-3) and (a-5) are performed simultaneously while performing the step (a-4).

3. The method according to claim 1, wherein the steps (a-3) and (a-5) are performed consecutively while performing the step (a-4).

4. A method of manufacturing a semiconductor device, comprising:
(a) transferring a first substrate from a first preliminary chamber into a first process chamber via a transfer chamber;
(b) processing the first substrate in the first process chamber; and
(c) transferring a second substrate from a second process chamber into a second preliminary chamber via the transfer chamber,
wherein the step (a) comprises:
(a-1) opening a first gate valve disposed between the first preliminary chamber and the transfer chamber;
(a-2) transferring the first substrate from the first preliminary chamber into the transfer chamber via a substrate transfer unit;
(a-3) closing the first gate valve;
(a-4) pivoting the substrate transfer unit in the transfer chamber with the first substrate thereon;
(a-5) opening a second gate valve disposed between the transfer chamber and the first process chamber;
(a-6) transferring the first substrate from the transfer chamber into the first process chamber; and
(a-7) closing the second gate valve,
wherein the step (c) comprises:
(c-1) opening a third gate valve disposed between the second process chamber and the transfer chamber;
(c-2) transferring the second substrate from the second process chamber into the transfer chamber via the substrate transfer unit;
(c-3) closing the third gate valve;
(c-4) pivoting the substrate transfer unit in the transfer chamber with the second substrate thereon;
(c-5) opening a fourth gate valve disposed between the second preliminary chamber and the transfer chamber;
(c-6) transferring the second substrate from the transfer chamber into the second preliminary chamber; and
(c-7) closing the fourth gate valve, and
wherein the steps (a-3) and (a-5) are performed while performing the step (a-4) and the steps (c-3) and (c-5) are performed while performing the step (c-4).

5. The method according to claim 4, the steps (a-3) and (a-5) are performed simultaneously while performing the step (a-4).

6. The method according to claim 4, the steps (a-3) and (a-5) are performed consecutively while performing the step (a-4).

7. The method according to claim 4, the steps (c-3) and (c-5) are performed simultaneously while performing the step (c-4).

8. The method according to claim 4, the steps (c-3) and (c-5) are performed consecutively while performing the step (c-4).

9. The method according to claim 4, wherein the step (c) starts while performing the step (a).

10. The method according to claim 9, wherein the step (a-7) and the step (c-1) are simultaneously performed.

11. The method according to claim 9, wherein the step (a-7) and the step (c-1) are consecutively performed.
